(19) United States
(12) Patent Application Publication
(10) Pub. No.: US 2024/0334591 A1
(43) Pub. Date: Oct. 3, 2024

(54) MODULE AND SEMICONDUCTOR COMPOSITE APPARATUS

(71) Applicant: Murata Manufacturing Co., Ltd., Nagaokakyo-shi (JP)

(72) Inventors: Takeshi FURUKAWA, Nagaokakyo-shi (JP); Tomoki KATO, Nagaokakyo-shi (JP)

(21) Appl. No.: 18/671,139

(22) Filed: May 22, 2024

Related U.S. Application Data
(63) Continuation of application No. PCT/JP2022/042187, filed on Nov. 14, 2022.

(30) Foreign Application Priority Data
Nov. 25, 2021 (JP) 2021-191266

(51) Int. Cl. H05K 1/02; H05K 1/14; H05K 1/16

(52) U.S. Cl. CPC H05K 1/0231; H05K 1/141; H05K 1/162; H05K 2201/10515

(57) ABSTRACT

A device may include a capacitor array that is configured with a plurality of capacitor portions disposed in a plane. A device may include a through-hole conductor that is provided to penetrate the capacitor portions in a thickness direction of the capacitor array and is used for electrical connection between the capacitor portions and at least one of the voltage regulator and the load. A device may include a connection terminal layer that is electrically connected to the through-hole conductor and is used for electrical connection between the capacitor portions and at least one of the voltage regulator and the load. A device may include the capacitor array includes at least a first and second capacitor array, and, when viewed from a mounting surface of the connection terminal layer, at least a part of the first and the second capacitor array overlap each other.

### CROSS REFERENCE TO RELATED APPLICATIONS

This application is a continuation of International Application No. PCT/JP2022/042187, filed Nov. 14, 2022, which claims priority to Japanese Patent Application No. 2021-191266, filed Nov. 25, 2021, the entire contents of each of which are hereby incorporated in their entirety.

### TECHNICAL FIELD

The present disclosure is directed to a module and a semiconductor composite apparatus.

### BACKGROUND ART

A semiconductor device, as described in U.S. Patent Application Publication No. 2011/0050334 (hereinafter, “U.S. '334”), includes a package substrate in which a part or all of passive elements, such as an inductor and a capacitor, are embedded, and a voltage regulator (voltage control apparatus) including an active element such as a switching element. In the semiconductor device described in U.S. '334, the voltage regulator and a load, to which a power supply voltage is to be supplied, are mounted on a package substrate. U.S. '334 further describes a direct current voltage adjusted by the voltage regulator is smoothed by the passive element in the package substrate and supplied to the load.

In the semiconductor device described in U.S. '334, in a case where a wiring path, in which a voltage regulator and a load are electrically connected with a passive element in a package substrate interposed therebetween, is long, a loss due to wiring, such as an increase in inductor components and resistance components due to wiring, is large. In particular, in the semiconductor device described in U.S. '334, in a case where a capacitor array in which a plurality of capacitors are arranged in an array is used as the passive element in the package substrate, it is difficult to shorten both a wiring path between the voltage regulator and each capacitor and a wiring path between the load and each capacitor, and, as a result, it is difficult to shorten the wiring path between the voltage regulator and the load as a result. In a case of a plurality of capacitor arrays, it is further difficult to shorten the wiring path between the voltage regulator and the load.

### SUMMARY OF INVENTION

The present disclosure has been made to solve the above-described problem, and an object of the present disclosure is to provide a module that reduces a loss due to wiring in a state of being incorporated in a semiconductor composite apparatus while having a plurality of capacitor arrays. Another object of the present disclosure is to provide a semiconductor composite apparatus including the module.

A module according to the present disclosure is a module used for a semiconductor composite apparatus in which a direct current voltage adjusted by a voltage regulator including a semiconductor active element is supplied to a load, the module including a capacitor array that is configured with a plurality of capacitor portions disposed in a plane, a through-hole conductor that is provided to penetrate the capacitor portions in a thickness direction of the capacitor array and is used for electrical connection between the capacitor portions and at least one of the voltage regulator and the load, and a connection terminal layer that is electrically connected to the through-hole conductor and is used for electrical connection between the capacitor portions and at least one of the voltage regulator and the load, in which the capacitor array includes at least a first capacitor array and a second capacitor array, and, when viewed from a mounting surface of the connection terminal layer, at least a part of the first capacitor array and at least a part of the second capacitor array overlap each other.

A semiconductor composite apparatus according to the present disclosure includes the module according to the present disclosure, the voltage regulator, and the load.

According to the present disclosure, a module is provided that reduces a loss due to wiring in a state of being incorporated in a semiconductor composite apparatus while having a plurality of capacitor arrays. In addition, according to the present disclosure, a semiconductor composite apparatus is provided that includes the module.

### BRIEF DESCRIPTION OF DRAWINGS

In the descriptions that follow, like parts are marked throughout the specification and drawings with the same numerals, respectively. The drawings are not necessarily drawn to scale and certain drawings may be shown in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a circuit configuration diagram illustrating an example of a circuit configuration of a semiconductor composite apparatus in accordance with aspects of the present disclosure;

FIG. 2 is a schematic cross-sectional view illustrating an example of a semiconductor composite apparatus in accordance with aspects of the present disclosure;

FIG. 3 is a schematic plan view illustrating a state in which the semiconductor composite apparatus illustrated in FIG. 2 is viewed from one mounting surface side of a module in accordance with aspects of the present disclosure;

FIG. 4 is a schematic plan view illustrating a state in which the semiconductor composite apparatus illustrated in FIG. 2 is viewed from the other mounting surface side of the module in accordance with aspects of the present disclosure;

FIG. 5 is a schematic cross-sectional view illustrating an example of an anode through-hole conductor, which is electrically connected to an anode of a capacitor portion, and the periphery thereof in accordance with aspects of the present disclosure;

FIG. 6 is a schematic cross-sectional view illustrating a projection state taken along the line segment A1-A2 in FIG. 5 in accordance with aspects of the present disclosure;

FIG. 7 is a schematic cross-sectional view illustrating an example of a cathode through-hole conductor, which is electrically connected to a cathode of the capacitor portion, and the periphery thereof in accordance with aspects of the present disclosure;

FIG. 8 is a schematic cross-sectional view illustrating a projection state taken along the line segment B1-B2 in FIG. 7 in accordance with aspects of the present disclosure;

FIG. 9 is a schematic cross-sectional view illustrating an example of a semiconductor composite apparatus in accordance with aspects of the present disclosure;

FIG. 10 is a schematic cross-sectional view illustrating an example of a semiconductor composite apparatus in accordance with aspects of the present disclosure;

FIG. 11 is a circuit configuration diagram illustrating another example of the circuit configuration of the semiconductor composite apparatus in accordance with aspects of the present disclosure;

### DETAILED DESCRIPTION OF EMBODIMENTS

Hereinafter, a module according to the present disclosure and a semiconductor composite apparatus according to the present disclosure will be described. The present disclosure is not limited to the following configurations, and may be modified as appropriate without departing from the gist of the present disclosure. In addition, the present disclosure also includes a combination of a plurality of individual preferred configurations described below.

The semiconductor composite apparatus according to aspects of the present disclosure includes the module according to the present disclosure, a voltage regulator, and a load.

FIG. 1 is a circuit configuration diagram illustrating an example of a circuit configuration of the semiconductor composite apparatus according to aspects of the present disclosure.

A semiconductor composite apparatus 1 illustrated in FIG. 1 includes a module 10, a voltage regulator 20, and a load 30.

In the example illustrated in FIG. 1, a first channel CH1 and a second channel CH2 are provided, and the number of channels is two. The number of channels may be one or three or greater. That is, the number of channels may be one or more.

The voltage regulator 20 includes a semiconductor active element. The voltage regulator 20 adjusts a direct current voltage supplied from the outside to a voltage level suitable for the load 30 by controlling the duty of the semiconductor active element.

In the example illustrated in FIG. 1, the voltage regulator 20 includes a switching element SW1, a switching element SW2, a switching element SW3, and a switching element SW4 as semiconductor active elements.

The switching element SW1 is provided in the first channel CH1.

The switching element SW2, the switching element SW3, and the switching element SW4 are provided in the second channel CH2.

The direct current voltage adjusted by the voltage regulator 20 is supplied to the load 30.

Examples of the load 30 include a semiconductor integrated circuit (IC) such as a logical operation circuit and a storage circuit.

The module according to aspects of the present disclosure is used for the semiconductor composite apparatus in which the direct current voltage adjusted by the voltage regulator including the semiconductor active element, to the load.

The module 10 is provided between the voltage regulator 20 and the load 30. As a result, the module 10 is used for the semiconductor composite apparatus 1 in which the direct current voltage, which is adjusted by the voltage regulator 20, is supplied to the load 30.

The module 10 includes a capacitor portion C1, a capacitor portion C2, a capacitor portion C3, and a capacitor portion C4.

The capacitor portion C1 and the capacitor portion C3 are provided in the first channel CH1. More specifically, the capacitor portion C1 and the capacitor portion C3 are provided between a ground terminal and a spot between the switching element SW1 and the load 30.

The capacitor portion C1 and the capacitor portion C3 may be connected in parallel as illustrated in FIG. 1, or may be connected in series.

The capacitor portion C2 and the capacitor portion C4 are provided in the second channel CH2. More specifically, the capacitor portion C2 and the capacitor portion C4 are provided between a ground terminal and the same point between the switching element SW2, the switching element SW3, and the switching element SW4 and the load 30.

The capacitor portion C2 and the capacitor portion C4 may be connected in parallel as illustrated in FIG. 1, or may be connected in series.

As illustrated in FIG. 1, the semiconductor composite apparatus 1 may further include an inductor L1, an inductor L2, an inductor L3, and an inductor L4.

The inductor L1 is provided in the first channel CH1. More specifically, the inductor L1 is provided between the switching element SW1 and the load 30. In this case, as illustrated in FIG. 1, the capacitor portion C1 and the capacitor portion C3 are provided between the ground terminal and a spot between the inductor L1 and the load 30.

The inductor L2, the inductor L3, and the inductor L4 are provided in the second channel CH2. More specifically, the inductor L2 is provided between the switching element SW2 and the load 30, the inductor L3 is provided between the switching element SW3 and the load 30, and the inductor L4 is provided between the switching element SW4 and the load 30. In this case, as illustrated in FIG. 1, the capacitor portion C2 and the capacitor portion C4 are provided between a ground terminal and the same point between the inductor L2, the inductor L3, and the inductor L4 and the load 30.

The inductor L1, the inductor L2, the inductor L3, and the inductor L4 may be included in the module 10.

The semiconductor composite apparatus 1 may further include electronic devices such as a decoupling capacitor for noise countermeasures, a choke inductor, a diode element for surge protection, and a resistive element for voltage division.

Hereinafter, the details of the configurations of the module aspects of the present disclosure and the semiconductor composite apparatus aspects of the present disclosure will be described with reference to the aspects.

Each aspect illustrated is an example, and it goes without saying that partial replacement or combination of configurations illustrated in different aspects is possible. In one aspect and subsequent aspects, descriptions of matters common to one aspect will be omitted, and different points will be mainly described. In particular, similar actions and effects due to similar configurations will not be mentioned sequentially for each aspect.

In the following description, in a case where the respective aspects are not particularly distinguished from each other, the “module according to the present disclosure” and the “semiconductor composite apparatus according to the present disclosure” are simply referred to.

The drawings illustrated are schematic diagrams, and the dimensions, aspect ratios, and the like may differ from an actual product.

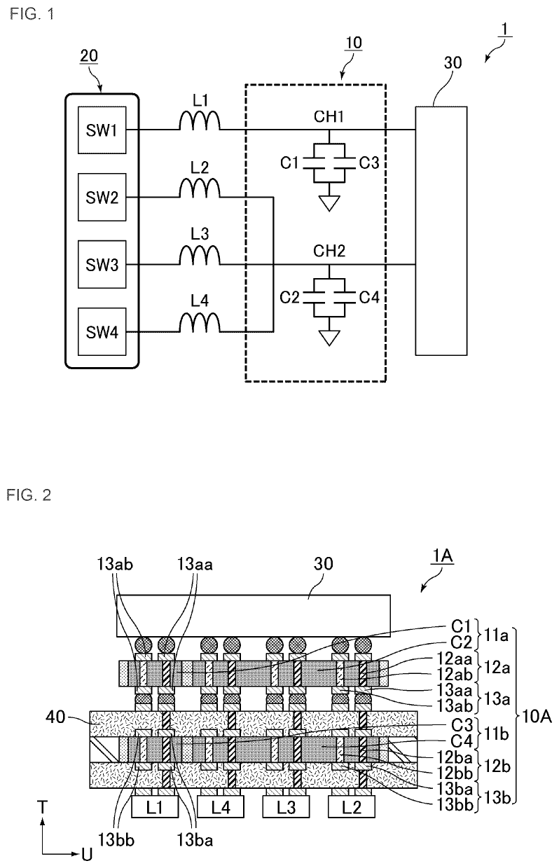

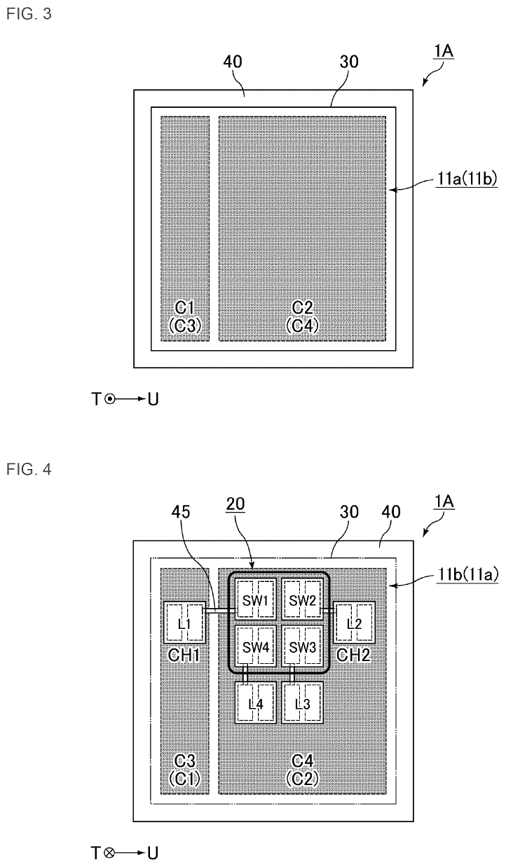

FIG. 2 is a schematic cross-sectional view illustrating an example of a semiconductor composite according to aspects of the present disclosure. FIG. 3 is a schematic plan view illustrating a state in which the semiconductor composite apparatus illustrated in FIG. 2 is viewed from one mounting surface side of the module. FIG. 4 is a schematic plan view illustrating a state in which the semiconductor composite apparatus illustrated in FIG. 2 is viewed from the other mounting surface side of the module.

In the present specification, as illustrated in FIG. 2 and the like, a thickness direction is defined as a direction defined by T. In addition, as illustrated in FIG. 2 and the like, a surface direction orthogonal to the thickness direction is defined as a direction defined by U. Although a plurality of surface directions U exist, one of the plurality of surface directions U is illustrated in a representative manner in FIG. 2 and the like.

A semiconductor composite apparatus 1A illustrated in FIGS. 2, 3, and 4 includes a module 10A, a voltage regulator 20, and a load 30.

As illustrated in FIGS. 2 and 3, in the semiconductor composite apparatus 1A, the load 30 is provided on one mounting surface side of the module 10A.

As illustrated in FIG. 4, in the semiconductor composite apparatus 1A, the voltage regulator 20 including the switching element SW1, the switching element SW2, the switching element SW3, and the switching element SW4 is provided on the other mounting surface side of the module 10A.

As illustrated in FIG. 4, in the semiconductor composite apparatus 1A, the inductor L1, the inductor L2, the inductor L3, and the inductor L4 are further provided on the other mounting surface side of the module 10A. The inductor L1, the inductor L2, the inductor L3, and the inductor L4 are electrically connected to the switching element SW1, the switching element SW2, the switching element SW3, and the switching element SW4, respectively, with the circuit layer 45 including the wiring and interposed therebetween.

The module according to aspects of the present disclosure includes a capacitor array that is configured with a plurality of capacitor portions disposed in a plane, a through-hole conductor that is provided to penetrate the capacitor portions in a thickness direction of the capacitor array and is used for electrical connection between the capacitor portions and at least one of the voltage regulator and the load, and a connection terminal layer that is electrically connected to the through-hole conductor and is used for electrical connection between the capacitor portions and at least one of the voltage regulator and the load.

In the module according to aspects of the present disclosure, the capacitor array includes at least a first capacitor array and a second capacitor array.

The module 10A illustrated in FIGS. 2,3, and 4 includes a first capacitor array 11a, a second capacitor array 11b, a first through-hole conductor 12a, a second through-hole conductor 12b, a first connection terminal layer 13a, and a second connection terminal layer 13b.

The first capacitor array 11a includes the plurality of capacitor portions disposed in a plane. In the examples illustrated in FIGS. 2, 3, and 4, the first capacitor array 11a includes two capacitor portions disposed in a plane, more specifically, a capacitor portion C1 and a capacitor portion C2.

When viewed from the thickness direction T, the areas of the capacitor portion C1 and the capacitor portion C2 may be the same as each other or different from each other.

The first capacitor array 11a may include three or more capacitor portions disposed in a plane.

The first through-hole conductor 12a is provided to penetrate the capacitor portion C1 or the capacitor portion C2 in the thickness direction T of the first capacitor array 11a. In the example illustrated in FIG. 2, the first through-hole conductor 12a includes a first through-hole conductor 12aa and a first through-hole conductor 12ab. The first through-hole conductor 12aa and the first through-hole conductor 12ab are provided to penetrate the capacitor portion C1 in the thickness direction T, and are provided to penetrate the capacitor portion C2 in the thickness direction T.

The first through-hole conductor 12a is used for electrical connection between the capacitor portion C1 and at least one of the voltage regulator 20 and the load 30. In the example illustrated in FIG. 2, each of the first through-hole conductor 12aa and the first through-hole conductor 12ab included in the first through-hole conductor 12a corresponding to the capacitor portion C1 is used for electrical connection between the capacitor portion C1 and the load 30.

The first through-hole conductor 12a is used for electrical connection between the capacitor portion C2 and at least one of the voltage regulator 20 and the load 30. In the example illustrated in FIG. 2, each of the first through-hole conductor 12aa and the first through-hole conductor 12ab included in the first through-hole conductor 12a corresponding to the capacitor portion C2 is used for electrical connection between the capacitor portion C2 and the load 30.

The first connection terminal layer 13a is electrically connected to the first through-hole conductor 12a. In the example illustrated in FIG. 2, the first connection terminal layer 13a includes a first connection terminal layer 13aa and a first connection terminal layer 13ab. The first connection terminal layer 13aa is provided on both ends of the first through-hole conductor 12aa, and is connected to the first through-hole conductor 12aa. The first connection terminal layers 13ab are provided on both ends of the first through-hole conductor 12ab and are connected to the first through-hole conductor 12ab.

The first connection terminal layer 13a is used for electrical connection between the capacitor portion C1 and at least one of the voltage regulator 20 and the load 30. In the example illustrated in FIG. 2, in the first connection terminal layer 13aa and the first connection terminal layer 13ab included in the first connection terminal layer 13a corresponding to the capacitor portion C1, the connection terminal layers (in FIG. 2, the first connection terminal layer 13aa and the first connection terminal layer 13ab on the upper side) that are present on the side of the load 30 are used for electrical connection between the capacitor portion C1 and the load 30.

The first connection terminal layer 13a is used for electrical connection between the capacitor portion C2 and at least one of the voltage regulator 20 and the load 30. In the example illustrated in FIG. 2, in the first connection terminal layer 13aa and the first connection terminal layer 13ab that are included in the first connection terminal layer 13a corresponding to the capacitor portion C2, the connection terminal layers (in FIG. 2, the first connection terminal layer 13aa and the first connection terminal layer 13ab on the upper side) that are present on the side of the load 30 are used for the electrical connection between the capacitor portion C2 and the load 30.

The second capacitor array 11b includes a plurality of capacitor portions disposed in a plane. In the examples illustrated in FIGS. 2, 3, and 4, the second capacitor array 11b includes two capacitor portions disposed in a plane, more specifically, the capacitor portion C3 and the capacitor portion C4.

When viewed from the thickness direction T, the areas of the capacitor portion C3 and the capacitor portion C4 may be the same as each other or different from each other.

The second capacitor array 11b may include three or more capacitor portions disposed in a plane.

The second through-hole conductor 12b is provided to penetrate the capacitor portion C3 or the capacitor portion C4 in the thickness direction T of the second capacitor array 11b. In the example illustrated in FIG. 2, the second through-hole conductor 12b includes a second through-hole conductor 12ba and a second through-hole conductor 12bb. The second through-hole conductor 12bb and the second through-hole conductor 12bb are provided to penetrate the capacitor portion C3 in the thickness direction T, and are provided to penetrate the capacitor portion C4 in the thickness direction T.

The second through-hole conductor 12b is used for electrical connection between the capacitor portion C3 and at least one of the voltage regulator 20 and the load 30. In the example illustrated in FIG. 2, the second through-hole conductor 12ba included in the second through-hole conductor 12b corresponding to the capacitor portion C3 is used for electrical connection between the capacitor portion C3 and the voltage regulator 20.

The second through-hole conductor 12b is used for electrical connection between the capacitor portion C4 and at least one of the voltage regulator 20 and the load 30. In the example illustrated in FIG. 2, the second through-hole conductor 12ba included in the second through-hole conductor 12b corresponding to the capacitor portion C4 is used for electrical connection between the capacitor portion C4 and the voltage regulator 20.

The second connection terminal layer 13b is electrically connected to the second through-hole conductor 12b. In the example illustrated in FIG. 2, the second connection terminal layer 13b includes a second connection terminal layer 13ba and a second connection terminal layer 13bb. The second connection terminal layer 13bb is provided on both ends of the second through-hole conductor 12ba and is connected to the second through-hole conductor 12ba. The second connection terminal layer 13bb is provided on both ends of the second through-hole conductor 12bb and is connected to the second through-hole conductor 12bb.

The second connection terminal layer 13b is used for electrical connection between the capacitor portion C3 and at least one of the voltage regulator 20 and the load 30. In the example illustrated in FIG. 2, the second connection terminal layer 13ba (in FIG. 2, the second connection terminal layer 13ba on the lower side) that is included in the second connection terminal layer 13b corresponding to the capacitor portion C3 and is present on the side of the voltage regulator 20 is used for electrical connection between the capacitor portion C3 and the voltage regulator 20.

The second connection terminal layer 13b is used for electrical connection between the capacitor portion C4 and at least one of the voltage regulator 20 and the load 30. In the example illustrated in FIG. 2, the second connection terminal layer 13ba (in FIG. 2, the second connection terminal layer 13ba on the lower side) that is included in the second connection terminal layer 13b corresponding to the capacitor portion C4 and is present on the side of the voltage regulator 20 is used for the electrical connection between the capacitor portion C4 and the voltage regulator 20.

As described above, in the semiconductor composite apparatus 1A, the voltage regulator 20 and the load 30 are electrically connected with the through-hole conductor and the connection terminal layer of the module 10A interposed therebetween. As a result, in the semiconductor composite apparatus 1A, a wiring path between the voltage regulator 20 and the load 30 is likely to be shortened, and, as a result, a loss due to wiring can be reduced.

In the module 10A, when viewed from a mounting surface of the first connection terminal layer 13a or the second connection terminal layer 13b, it is preferable that at least a part of the first through-hole conductor 12aa, at least a part of the first connection terminal layer 13aa, at least a part of the second through-hole conductor 12ba, and at least a part of the second connection terminal layer 13ba overlap each other. Alternatively, in the module 10A, when viewed from the mounting surface of the first connection terminal layer 13a or the second connection terminal layer 13b, it is preferable that the first through-hole conductor 12aa, the first connection terminal layer 13aa, the second through-hole conductor 12ba, and the second connection terminal layer 13ba are positioned on the same straight line along the thickness direction T.

In the module 10A, when viewed from the mounting surface of the first connection terminal layer 13a or the second connection terminal layer 13b, it is preferable that at least a part of the first through-hole conductor 12ab, at least a part of the first connection terminal layer 13ab, at least a part of the second through-hole conductor 12bb, and at least a part of the second connection terminal layer 13bb overlap each other. Alternatively, in the module 10A, when viewed from the mounting surface of the first connection terminal layer 13a or the second connection terminal layer 13b, it is preferable that the first through-hole conductor 12ab, the first connection terminal layer 13ab, the second through-hole conductor 12bb, and the second connection terminal layer 13bb are positioned on the same straight line along the thickness direction T.

In the module according to aspects of the present disclosure, when viewed from the mounting surface of the connection terminal layer, at least a part of the first capacitor array and at least a part of the second capacitor array overlap each other.

In the module 10A, when viewed from the mounting surface of the first connection terminal layer 13a or the second connection terminal layer 13b, at least a part of the first capacitor array 11a and at least a part of the second capacitor array 11b overlap each other. More specifically, in the module 10A, when viewed from the mounting surface of the first connection terminal layer 13a or the second connection terminal layer 13b, at least a part of the capacitor portions (in the examples illustrated in FIGS. 3 and 4, the capacitor portion C1 and the capacitor portion C2) forming the first capacitor array 11a and at least a part of the capacitor portions (in the examples illustrated in FIGS. 3 and 4, the capacitor portion C3 and the capacitor portion C4) forming the second capacitor array 11b overlap each other.

In the examples illustrated in FIGS. 3 and 4, when viewed from the mounting surface of the first connection terminal layer 13a or the second connection terminal layer 13b, the entire or a portion of the first capacitor array 11a and the entire or a portion of the second capacitor array 11b overlap each other. As described above, in the module 10A, when viewed from the mounting surface of the first connection terminal layer 13a or the second connection terminal layer 13b, it is preferable that the entire or a portion of the first capacitor array 11a and the entire or a portion of the second capacitor array 11b overlap each other.

In the module 10A, when viewed from the mounting surface of the first connection terminal layer 13a or the second connection terminal layer 13b, a part of the first capacitor array 11a and a part of the second capacitor array 11b may overlap each other, the entire or a portion of the first capacitor array 11a and a part of the second capacitor array 11b may overlap each other, or a part of the first capacitor array 11a and the entire or a portion of the second capacitor array 11b may overlap each other.

In the module 10A, when viewed from the mounting surface of the first connection terminal layer 13a or the second connection terminal layer 13b, at least a part of the first capacitor array 11a and at least a part of the second capacitor array 11b overlap each other, and thus the first capacitor array 11a and the second capacitor array 11b are not disposed on the same plane that spreads in the surface direction U. Therefore, a wiring path between the first capacitor array 11a and the second capacitor array 11b is likely to be shortened, and, as a result, the loss due to wiring can be reduced.

In the module according to aspects of the present disclosure, by sequentially observing cross sections along the thickness direction in the surface direction using an X-ray CT apparatus or the like, it is possible to confirm how deep the capacitor array is and what size the capacitor array has in the surface direction. In this manner, in the module according to aspects of the present disclosure, when viewed from the mounting surface of the connection terminal layer, it is possible to confirm that at least a part of the first capacitor array and at least a part of the second capacitor array overlap each other.

As described above, according to the module 10A, the loss due to wiring in a state of being incorporated in the semiconductor composite apparatus 1A can be reduced while having a plurality of capacitor arrays.

In addition, according to the module 10A, the first capacitor array 11a and the second capacitor array 11b are not disposed on the same plane that spreads in the surface direction U, and thus the mounting area of the module 10A in a state of being incorporated in the semiconductor composite apparatus 1A is likely to be small, and, as a result, the size of the semiconductor composite apparatus 1A can be reduced.

Further, according to the module 10A, the multilayered capacitor array including the first capacitor array 11a and the second capacitor array 11b is provided, and thus the diversification is possible as the capacitance density is increased by connecting the respective capacitor arrays in parallel, a withstanding voltage is increased by connecting the respective capacitor arrays in series, and it is possible to correspond to a plurality of voltage channels by disposing a capacitor array having different withstanding voltages.

In the module according to aspects of the present disclosure, it is preferable that the difference between the withstanding voltage of the first capacitor array and the withstanding voltage of the second capacitor array is 1 V or greater.

In the module 10A, it is preferable that the difference between the withstanding voltage of the first capacitor array 11a and the withstanding voltage of the second capacitor array 11b is 1 V or greater.

In a case where the difference between the withstanding voltage of the first capacitor array 11a and the withstanding voltage of the second capacitor array 11b is 1 V or greater, the withstanding voltage of the first capacitor array 11a may be greater than the withstanding voltage of the second capacitor array 11b or may be less than the withstanding voltage of the second capacitor array 11b.

On the other hand, it is preferable that the difference between the withstanding voltage of the first capacitor array 11a and the withstanding voltage of the second capacitor array 11b is 48 V or less.

In the semiconductor composite apparatus according to aspects of the present disclosure, when viewed from the mounting surface of the connection terminal layer, it is preferable that at least a part of the semiconductor active element included in the voltage regulator overlaps the first capacitor array and the second capacitor array.

In the semiconductor composite apparatus 1A, when viewed from the mounting surface of the first connection terminal layer 13a or the second connection terminal layer 13b, it is preferable that at least a part of the semiconductor active element included in the voltage regulator 20 overlaps the first capacitor array 11a and the second capacitor array 11b.

In the example illustrated in FIG. 4, when viewed from the mounting surface of the second connection terminal layer 13b, all or a portion of the switching element SW1, the switching element SW2, the switching element SW3, and the switching element SW4, which are provided as the semiconductor active elements included in the voltage regulator 20, overlap the first capacitor array 11a and the second capacitor array 11b. In this way, in the semiconductor composite apparatus 1A, when viewed from the mounting surface of the first connection terminal layer 13a or the second connection terminal layer 13b, it is particularly preferable that all or a portion of the semiconductor active elements included in the voltage regulator 20 overlap the first capacitor array 11a and the second capacitor array 11b.

In the semiconductor composite apparatus 1A, when viewed from the mounting surface of the first connection terminal layer 13a or the second connection terminal layer 13b, a part of the semiconductor active element included in the voltage regulator 20 may overlap the first capacitor array 11a and the second capacitor array 11b.

In a case where the voltage regulator 20 includes a plurality of semiconductor active elements, the “part of the semiconductor active element included in the voltage regulator 20” may mean a number of semiconductor active elements of a part of the plurality of semiconductor active elements or may mean a part of the disposition area of the plurality of semiconductor active elements.

In the semiconductor composite apparatus 1A, when viewed from the mounting surface of the first connection terminal layer 13a or the second connection terminal layer 13b, at least a part of the semiconductor active element included in the voltage regulator 20 overlaps the first capacitor array 11a and the second capacitor array 11b, and thus the first capacitor array 11a and the second capacitor array 11b are configured to be provided at positions adjacent to the semiconductor active element in the thickness direction T. Therefore, in the semiconductor composite apparatus 1A, the first capacitor array 11a and the second capacitor array 11b are configured to form a Point Of Load (POL) integrated with a power supply functional element called a switching element as a semiconductor active element.

In the semiconductor composite apparatus according to aspects of the present disclosure, when viewed from the mounting surface of the connection terminal layer, it is preferable that at least a part of the first capacitor array and at least a part of the second capacitor array overlap the load.

In the semiconductor composite apparatus 1A, when viewed from the mounting surface of the first connection terminal layer 13a or the second connection terminal layer 13b, it is preferable that at least a part of the first capacitor array 11a and at least a part of the second capacitor array 11b overlap the load 30.

In the examples illustrated in FIGS. 3 and 4, when viewed from the mounting surface of the first connection terminal layer 13a or the second connection terminal layer 13b, the entire or a portion of the first capacitor array 11a and the entire or a portion of the second capacitor array 11b overlap the load 30. In this manner, in the semiconductor composite apparatus 1A, when viewed from the mounting surface of the first connection terminal layer 13a or the second connection terminal layer 13b, it is particularly preferable that the entire or a portion of the first capacitor array 11a and the entire or a portion of the second capacitor array 11b overlap the load 30.

In the semiconductor composite apparatus 1A, when viewed from the mounting surface of the first connection terminal layer 13a or the second connection terminal layer 13b, a part of the first capacitor array 11a and a part of the second capacitor array 11b may overlap the load 30, the entire or a portion of the first capacitor array 11a and a part of the second capacitor array 11b may overlap the load 30, or a part of the first capacitor array 11a and the entire or a portion of the second capacitor array 11b may overlap the load 30.

In the semiconductor composite apparatus 1A, when viewed from the mounting surface of the first connection terminal layer 13a or the second connection terminal layer 13b, at least a part of the first capacitor array 11a and at least a part of the second capacitor array 11b overlap the load 30, and thus the first capacitor array 11a and the load 30 are not disposed on the same plane that spreads in the surface direction U, and the second capacitor array 11b and the load 30 are not disposed on the same plane that spreads in the surface direction U. Therefore, in the semiconductor composite apparatus 1A, a wiring path between the multilayered capacitor array including the first capacitor array 11a and the second capacitor array 11b and the load 30 is likely to be shortened, and, as a result, the loss due to wiring can be reduced. Further, in the semiconductor composite apparatus 1A, the mounting area between the multilayered capacitor array and the load 30 is likely to be small, and, as a result, the size of the semiconductor composite apparatus 1A can be reduced.

The semiconductor composite apparatus according to aspects of the present disclosure may further include a wiring board that is electrically connected to the voltage regulator and the load.

As illustrated in FIGS. 2, 3, and 4, the semiconductor composite apparatus 1A may further include a wiring board 40.

The wiring board 40 is electrically connected to the voltage regulator 20 and the load 30.

In the examples illustrated in FIGS. 2 and 3, the load 30 is electrically connected to one mounting surface of the wiring board 40 with the first through-hole conductor 12a and the first connection terminal layer 13a interposed therebetween.

In the examples illustrated in FIGS. 2 and 4, the switching element SW1, the switching element SW2, the switching element SW3, and the switching element SW4, which are provided as the semiconductor active element included in the voltage regulator 20, are electrically connected to the other mounting surface of the wiring board 40. Similarly, the inductor L1, the inductor L2, the inductor L3, and the inductor L4 are also electrically connected to the other mounting surface of the wiring board 40.

In the semiconductor composite apparatus according to aspects of the present disclosure, one of the first capacitor array and the second capacitor array may be provided on a mounting surface of the wiring board, and the other of the first capacitor array and the second capacitor array may be built in the wiring board.

In the semiconductor composite apparatus 1A, one of the first capacitor array 11a and the second capacitor array 11b may be provided on a mounting surface of the wiring board 40, and the other of the first capacitor array 11a and the second capacitor array 11b may be built in the wiring board 40.

In the example illustrated in FIG. 2, the first capacitor array 11a is provided on one mounting surface of the wiring board 40, and the second capacitor array 11b is built in the wiring board 40. In addition, the second through-hole conductor 12b and the second connection terminal layer 13b corresponding to the second capacitor array 11b are also built in the wiring board 40.

The first capacitor array 11a may be built in the wiring board 40. In addition, the second capacitor array 11b may be provided on one or the other mounting surface of the wiring board 40. For example, the first capacitor array 11a may be built in the wiring board 40, and the second capacitor array 11b may be provided on the other mounting surface of the wiring board 40.

In the semiconductor composite apparatus 1A, in a case where one of the first capacitor array 11a and the second capacitor array 11b is built in the wiring board 40, the size of the semiconductor composite apparatus 1A can be reduced as compared with a case where both the first capacitor array 11a and the second capacitor array 11b are provided on the mounting surface of the wiring board 40.

Hereinafter, specific examples of the capacitor portion, the through-hole conductor, and the connection terminal layer in the module according to aspects of the present disclosure will be illustrated.

In the module of the present disclosure, the through-hole conductor includes, for example, an anode through-hole conductor that is provided on at least an inner wall surface of the anode penetration hole penetrating the capacitor portion in the thickness direction and is electrically connected to the anode of the capacitor portion. In this case, it is preferable that the anode through-hole conductor is electrically connected to the anode of the capacitor portion on the inner wall surface of the anode penetration hole.

In the module according to aspects of the present disclosure, in a case where the through-hole conductor includes the anode through-hole conductor, the connection terminal layer includes, for example, an anode connection terminal layer provided on a surface of the anode through-hole conductor.

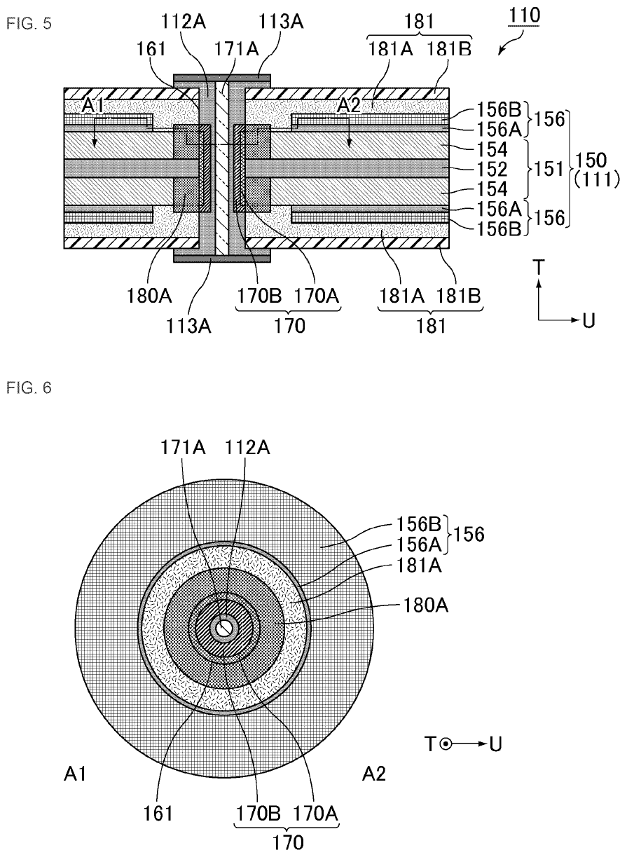

FIG. 5 is a schematic cross-sectional view illustrating an example of the anode through-hole conductor, which is electrically connected to an anode of the capacitor portion, and the periphery thereof. FIG. 6 is a schematic cross-sectional view illustrating a projection state taken along the line segment A1-A2 in FIG. 5.

A module 110 illustrated in FIG. 5 includes a capacitor array 111, an anode through-hole conductor 112A, and an anode connection terminal layer 113A.

The capacitor array 111 includes a capacitor portion 150. Although FIG. 5 illustrates a part of the capacitor array 111, a plurality of capacitor portions 150 are two-dimensionally arranged in the capacitor array 111.

The capacitor portion 150 includes an anode plate 151, a dielectric layer (not shown), and a cathode layer 156.

The anode plate 151 forms an anode of the capacitor portion 150.

The anode plate 151 includes a core portion 152 and a porous layer 154.

The core portion 152 is preferably made of metal, and is more preferably made of a valve action metal among these.

Examples of the valve action metal include a single metal such as aluminum, tantalum, niobium, titanium, or zirconium, and an alloy containing at least one of the single metals. Among these, aluminum or an aluminum alloy is preferable.

The porous layer 154 is provided on at least one main surface of the core portion 152. That is, the porous layer 154 may be provided on only one main surface of the core portion 152 or may be provided on both main surfaces of the core portion 152 as illustrated in FIG. 5. As described above, the anode plate 151 has the porous layer 154 on at least one main surface.

The porous layer 154 is preferably an etching layer obtained by etching the surface of the anode plate 151.

The shape of the anode plate 151 is preferably a flat plate shape and more preferably a foil shape. In the present specification, the term “plate shape” also includes “foil shape”.

The dielectric layer is provided on a surface of the porous layer 154. More specifically, the dielectric layer is provided along the surface (contour) of each hole present in the porous layer 154.

It is preferable that the dielectric layer consists of the above-mentioned oxide film of the valve action metal. For example, in a case where the anode plate 151 is an aluminum foil, an anodization treatment (also referred to as a chemical conversion treatment) is performed on the anode plate 151 in an aqueous solution containing ammonium adipate or the like, and thus the oxide film serving as the dielectric layer is formed. Since the dielectric layer is formed along the surface of the porous layer 154, the dielectric layer is provided with pores (recesses).

The cathode layer 156 forms a cathode of the capacitor portion 150.

The cathode layer 156 is provided on a surface of the dielectric layer.

As illustrated in FIG. 5, it is preferable that the cathode layer 156 has a solid electrolyte layer 156A provided on the surface of the dielectric layer and a conductor layer 156B provided on the surface of the solid electrolyte layer 156A.

Examples of a constituent material of the solid electrolyte layer 156A include conductive polymers such as polypyrroles, polythiophenes, and polyanilines. Among these, polythiophenes are preferable, and poly (3,4-ethylenedioxythiophene) (PEDOT) is particularly preferable. In addition, the conductive polymers may contain a dopant such as polystyrene sulfonic acid (PSS).

It is preferable that the solid electrolyte layer 156A includes an inner layer that is filled in the pores (recesses) of the dielectric layer and an outer layer that covers the surface of the dielectric layer.

It is preferable that the conductor layer 156B includes at least one of a conductive resin layer and a metal layer. That is, the conductor layer 156B may include only the conductive resin layer, may include only the metal layer, or may include both the conductive resin layer and the metal layer.

Examples of the conductive resin layer include a conductive adhesive layer containing at least one conductive filler selected from the group consisting of a silver filler, a copper filler, a nickel filler, and a carbon filler.

Examples of the metal layer include a metal plating film and a metal foil. It is preferable that the metal layer is made of at least one metal selected from the group consisting of nickel, copper, silver, and an alloy containing at least one of the metals as a main component.

In the present specification, the main component means an element component having the highest weight percentage.

The conductor layer 156B may include, for example, a carbon layer provided on the surface of the solid electrolyte layer 156A and a copper layer provided on the surface of the carbon layer.

The carbon layer is formed in a predetermined region by, for example, coating the surface of the solid electrolyte layer 156A with a carbon paste using a sponge transfer method, a screen printing method, a dispenser coating method, an ink jet printing method, or the like.

The copper layer is formed in a predetermined region by, for example, coating the surface of the carbon layer with a copper paste using the sponge transfer method, the screen printing method, a spray coating method, the dispenser coating method, the ink jet printing method, or the like.

As described above, the capacitor portion 150 illustrated in FIG. 5 has the anode plate 151 having the porous layer 154 on at least one main surface, the dielectric layer provided on the surface of the porous layer 154, and the cathode layer 156 provided on the surface of the dielectric layer. As a result, the capacitor portion 150 forms an electrolytic capacitor. In a case where the cathode layer 156 has the solid electrolyte layer 156A, the capacitor portion 150 constitutes a solid electrolytic capacitor.

In an exemplary aspect, the capacitor portion can form a ceramic capacitor using barium titanate or a thin film capacitor using silicon nitride (SiN), silicon dioxide (SiO₂), hydrogen fluoride (HF), or the like. However, from the viewpoint of thinning and increasing the area of the capacitor portion and improving mechanical characteristics such as rigidity and flexibility of the capacitor portion, it is preferable that the capacitor portion forms a capacitor having a metal such as aluminum as a base material, it is more preferable that the capacitor portion forms an electrolytic capacitor having a metal such as aluminum as a base material, and it is further preferable that the capacitor portion forms an electrolytic capacitor having aluminum or an aluminum alloy as a base material.

The anode through-hole conductor 112A is provided to penetrate the capacitor portion 150 in the thickness direction T of the capacitor array 111. In the example illustrated in FIG. 5, the anode through-hole conductor 112A is provided on at least an inner wall surface of the anode penetration hole 161 penetrating the capacitor portion 150 in the thickness direction T and is electrically connected to the anode plate 151.

It is preferable that the anode through-hole conductor 112A is electrically connected to the anode plate 151 on the inner wall surface of the anode penetration hole 161. In the example illustrated in FIG. 5, the anode through-hole conductor 112A is electrically connected to the end surface of the anode plate 151 facing the inner wall surface of the anode penetration hole 161 in the surface direction U.

As illustrated in FIG. 5, it is preferable that the core portion 152 and the porous layer 154 are exposed on the end surface of the anode plate 151 electrically connected to the anode through-hole conductor 112A. In this case, in addition to the core portion 152, the porous layer 154 is also electrically connected to the anode through-hole conductor 112A.

The anode through-hole conductor 112A is formed, for example, as follows. First, the anode penetration hole 161 is formed by performing a drilling processing, a laser processing, or the like on a portion where the anode through-hole conductor 112A is to be formed. Then, the inner wall surface of the anode penetration hole 161 is metallized with a low-resistance metal such as copper, gold, or silver, and thus the anode through-hole conductor 112A is formed. In a case of forming the anode through-hole conductor 112A, for example, the inner wall surface of the anode penetration hole 161 is metallized by an electroless copper plating treatment, an electrolytic copper plating treatment, or the like, and thus the processing is facilitated. In addition, a method of forming the anode through-hole conductor 112A may be a method of filling the anode penetration hole 161 with a metal, a composite material of a metal and a resin, or the like, in addition to a method of metallizing the inner wall surface of the anode penetration hole 161.

As illustrated in FIG. 5, it is preferable that the module 110 further includes an anode connection layer 170 provided between the anode through-hole conductor 112A and an end surface of the anode plate 151. In the example illustrated in FIG. 5, the anode connection layer 170 is in contact with both the anode through-hole conductor 112A and the end surface of the anode plate 151.

By providing the anode connection layer 170 between the anode through-hole conductor 112A and the end surface of the anode plate 151, the anode connection layer 170 functions as a barrier layer with respect to the anode plate 151, more specifically, as a barrier layer with respect to the core portion 152 and the porous layer 154. By using such an anode connection layer 170, the dissolution of the end surface of the anode plate 151 that occurs during the chemical liquid treatment for forming the anode connection terminal layer 113A and the like, which will be described later, is suppressed, and thus the infiltration of chemical liquid into the capacitor portion 150 is suppressed. Therefore, the reliability of the capacitor portion 150 is likely to be improved, and as a result, the reliability of the module 110 is likely to be improved.

As illustrated in FIG. 5, it is preferable that the anode through-hole conductor 112A and the end surface of the anode plate 151 are electrically connected to each other with the anode connection layer 170 interposed therebetween.

As illustrated in FIG. 5, the anode connection layer 170 may include a first anode connection layer 170A and a second anode connection layer 170B in order from the end surface side of the anode plate 151.

In the anode connection layer 170, for example, the first anode connection layer 170A may be a layer containing zinc as a main component, and the second anode connection layer 170B may be a layer containing nickel or copper as a main component. In this case, the first anode connection layer 170A is formed on the end surface of the anode plate 151 by, for example, substituting and precipitating zinc by a zincate treatment, and then the second anode connection layer 170B is formed on the surface of the first anode connection layer 170A by, for example, an electroless nickel plating treatment or an electroless copper plating treatment. There is a case where the first anode connection layer 170A disappears during the formation of the second anode connection layer 170B. In this case, the anode connection layer 170 may consist of only the second anode connection layer 170B.

The anode connection layer 170 preferably includes a layer containing nickel as a main component. In this case, since the damage to the metal (for example, aluminum) or the like forming the anode plate 151 is reduced, the barrier property of the anode connection layer 170 with respect to the anode plate 151 is likely to be improved.

As illustrated in FIG. 5, it is preferable that the dimension of the anode connection layer 170 is greater than the dimension of the anode plate 151 in the thickness direction T. In this case, since the entire or a portion of the end surface of the anode plate 151 is covered with the anode connection layer 170, the barrier property of the anode connection layer 170 with respect to the anode plate 151 is likely to be improved.

In the thickness direction T, it is preferable that the dimension of the anode connection layer 170 is greater than 100% and is 200% or less of the dimension of the anode plate 151.

In the thickness direction T, the dimension of the anode connection layer 170 may be the same as the dimension of the anode plate 151 or may be less than the dimension of the anode plate 151.

The anode connection layer 170 does not need to be provided between the anode through-hole conductor 112A and the end surface of the anode plate 151. In this case, the anode through-hole conductor 112A may be directly connected to the end surface of the anode plate 151.

As illustrated in FIG. 6, when viewed from the thickness direction T, it is preferable that the anode through-hole conductor 112A is electrically connected to the end surface of the anode plate 151 over the entire or a portion of the circumference of the anode penetration hole 161. In a case where the anode connection layer 170 is provided between the anode through-hole conductor 112A and the end surface of the anode plate 151, it is preferable that the anode through-hole conductor 112A is connected to the anode connection layer 170 over the entire or a portion of the circumference of the anode penetration hole 161 when viewed from the thickness direction T. In this case, since the contact area between the anode through-hole conductor 112A and the anode connection layer 170 is increased, the connection resistance between the anode through-hole conductor 112A and the anode connection layer 170 is likely to be reduced. As a result, the connection resistance between the anode through-hole conductor 112A and the anode plate 151 is likely to be reduced, and thus the Equivalent Series Resistance (ESR) of the capacitor portion 150 is likely to be reduced. Further, since the adhesion between the anode through-hole conductor 112A and the anode connection layer 170 is likely to be improved, a problem such as peeling between the anode through-hole conductor 112A and the anode connection layer 170 due to thermal stress is less likely to occur.

The anode connection terminal layer 113A is electrically connected to the anode through-hole conductor 112A. In the example illustrated in FIG. 5, the anode connection terminal layer 113A is provided on the surface of the anode through-hole conductor 112A. The anode connection terminal layer 113A functions as a connection terminal of the capacitor portion 150.

Examples of a constituent material of the anode connection terminal layer 113A include a low-resistance metal, such as silver, gold, or copper. In this case, the anode connection terminal layer 113A is formed, for example, by performing a plating treatment on the surface of the anode through-hole conductor 112A.

In order to improve the adhesion between the anode connection terminal layer 113A and the other member, here, in order to improve the adhesion between the anode connection terminal layer 113A and the anode through-hole conductor 112A, a mixed material of a resin and at least one conductive filler selected from the group consisting of a silver filler, a copper filler, a nickel filler, and a carbon filler may be used as a constituent material of the anode connection terminal layer 113A.

As illustrated in FIGS. 5 and 6, it is preferable that the module 110 further includes a first resin filling portion 171A in which the anode penetration hole 161 is filled with a resin material. In the examples illustrated in FIGS. 5 and 6, the first resin filling portion 171A is provided in a space surrounded by the anode through-hole conductor 112A on the inner wall surface of the anode penetration hole 161. In a case where the first resin filling portion 171A is provided to eliminate the space in the anode penetration hole 161, the occurrence of delamination of the anode through-hole conductor 112A is suppressed.

It is preferable that the coefficient of thermal expansion of the first resin filling portion 171A is greater than the coefficient of thermal expansion of the anode through-hole conductor 112A. More specifically, it is preferable that the coefficient of thermal expansion of the resin material with which the anode penetration hole 161 is filled is greater than the coefficient of thermal expansion of the constituent material (for example, copper) of the anode through-hole conductor 112A. In this case, in a case where the first resin filling portion 171A, more specifically, the resin material filled in the anode penetration hole 161 expands in the high temperature environment, the anode through-hole conductor 112A is pressed against the inner wall surface of the anode penetration hole 161 from the inner side portion toward the outer side portion of the anode penetration hole 161, and thus the occurrence of delamination of the anode through-hole conductor 112A is sufficiently suppressed.

The coefficient of thermal expansion of the first resin filling portion 171A may be the same as the coefficient of thermal expansion of the anode through-hole conductor 112A or may be less than the coefficient of thermal expansion of the anode through-hole conductor 112A. More specifically, the coefficient of thermal expansion of the resin material with which the anode penetration hole 161 is filled may be the same as the coefficient of thermal expansion of the constituent material of the anode through-hole conductor 112A or may be less than the coefficient of thermal expansion of the constituent material of the anode through-hole conductor 112A.

The module 110 does not need to have the first resin filling portion 171A. In this case, it is preferable that the anode through-hole conductor 112A is provided not only on the inner wall surface of the anode penetration hole 161 but also on the entire or a portion of the inside of the anode penetration hole 161.

As illustrated in FIG. 5, it is preferable that the module 110 further includes a first insulating layer 180A in which the porous layer 154 is filled with an insulating material. In this case, the insulation between the anode plate 151 and the cathode layer 156 is secured, and thus the short circuit therebetween is prevented.

As illustrated in FIG. 5, it is preferable that the first insulating layer 180A is provided not only inside the porous layer 154 but also on the surface of the capacitor array 111, more specifically, on the surface of the dielectric layer in which the cathode layer 156 is not present on the surface of the capacitor portion 150. In this case, the insulation between the anode plate 151 and the cathode layer 156 is sufficiently secured, and thus the short circuit therebetween is sufficiently prevented.

As illustrated in FIGS. 5 and 6, it is preferable that the first insulating layer 180A is provided around the anode through-hole conductor 112A. In this case, the insulation between the anode plate 151 and the cathode layer 156 is sufficiently secured, and thus the short circuit therebetween is sufficiently prevented. Further, since the first insulating layer 180A functions as a barrier layer with respect to the anode plate 151, more specifically, as a barrier layer with respect to the core portion 152 and the porous layer 154, the dissolution of the end surface of the anode plate 151 that occurs during the chemical liquid treatment for forming the anode connection terminal layer 113A and the like is suppressed, and thus the infiltration of chemical liquid into the capacitor portion 150 is suppressed. Therefore, the reliability of the capacitor portion 150 is likely to be improved, and as a result, the reliability of the module 110 is likely to be improved.

From the viewpoint of enhancing the above-described effect, as illustrated in FIG. 5, it is preferable that the dimension of the first insulating layer 180A is greater than the dimension of the porous layer 154 in the thickness direction T.

Examples of a constituent material of the first insulating layer 180A include a resin material such as epoxy, phenol, or polyimide, and a mixed material of the resin material such as epoxy, phenol, or polyimide and an inorganic filler such as silica or alumina.

As illustrated in FIG. 5, it is preferable that the module 110 further includes an insulating portion 181 provided on the surface of the capacitor array 111, more specifically, on the surface of the capacitor portion 150.

As illustrated in FIG. 5, it is preferable that the insulating portion 181 includes a first insulating portion 181A provided on the surface of the capacitor portion 150 and a second insulating portion 181B provided on the surface of the first insulating portion 181A.

Examples of the constituent materials of the first insulating portion 181A and the second insulating portion 181B include a resin material such as epoxy, phenol, or polyimide, and a mixed material of the resin material such as epoxy, phenol, or polyimide and an inorganic filler such as silica or alumina.

The constituent material of the first insulating portion 181A and the constituent material of the second insulating portion 181B may be the same as each other or different from each other.

In the module according to aspects of the present disclosure, the through-hole conductor includes, for example, a cathode through-hole conductor that is provided on at least an inner wall surface of the cathode penetration hole penetrating the capacitor portion in the thickness direction and is electrically connected to the cathode of the capacitor portion.

In the module according to aspects of the present disclosure, in a case where the through-hole conductor includes the cathode through-hole conductor, the connection terminal layer includes, for example, a cathode connection terminal layer provided on a surface of the cathode through-hole conductor.

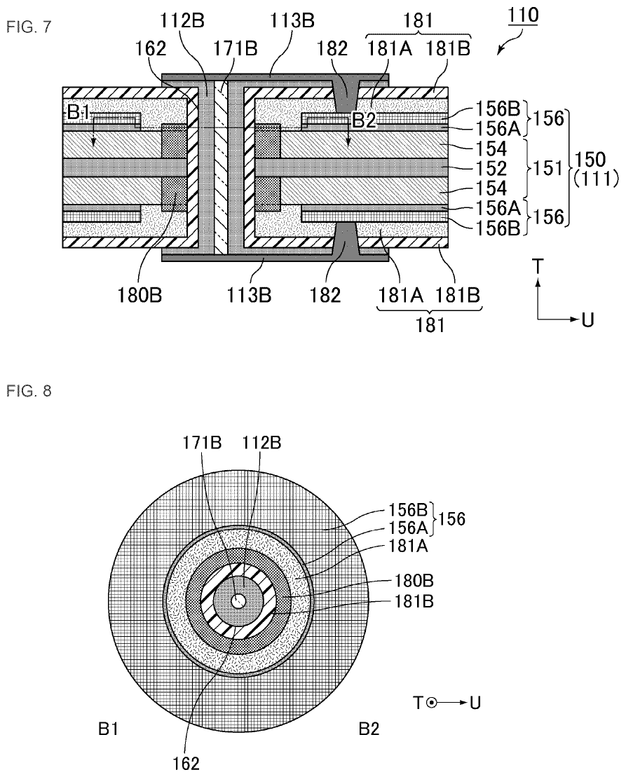

FIG. 7 is a schematic cross-sectional view illustrating an example of a cathode through-hole conductor, which is electrically connected to the cathode of the capacitor portion, and the periphery thereof. FIG. 8 is a schematic cross-sectional view illustrating a projection state taken along the line segment B1-B2 in FIG. 7.

A module 110 illustrated in FIG. 7 includes a capacitor array 111, a cathode through-hole conductor 112B, and a cathode connection terminal layer 113B.

The cathode through-hole conductor 112B is provided to penetrate the capacitor portion 150 in the thickness direction T of the capacitor array 111. In the example illustrated in FIG. 7, the cathode through-hole conductor 112B is provided on at least an inner wall surface of the cathode penetration hole 162 penetrating the capacitor portion 150 in the thickness direction T and is electrically connected to the cathode layer 156.

Here, in the example illustrated in FIG. 7, as an aspect in which the cathode connection terminal layer 113B is electrically connected to the cathode through-hole conductor 112B, the cathode connection terminal layer 113B is provided on the surface of the cathode through-hole conductor 112B and functions as a connection terminal of the capacitor portion 150. In addition, in the example illustrated in FIG. 7, the via conductor 182 is provided to penetrate the insulating portion 181 in the thickness direction T and to be connected to the cathode connection terminal layer 113B and the cathode layer 156. Therefore, in the example illustrated in FIG. 7, the cathode through-hole conductor 112B is electrically connected to the cathode layer 156 with the cathode connection terminal layer 113B and the via conductor 182 interposed therebetween. In this case, the size of the module 110 can also be reduced.

The cathode through-hole conductor 112B is formed, for example, as follows. First, penetration holes are formed by performing a drilling processing, a laser processing, or the like on a portion where the cathode through-hole conductor 112B is to be formed. Next, the insulating layer is formed by filling the formed penetration hole with a constituent material (for example, a resin material) of the second insulating portion 181B. Then, the cathode penetration hole 162 is formed by performing a drilling processing, a laser processing, or the like on the formed insulating layer. In this case, by setting the diameter of the cathode penetration hole 162 to be less than the diameter of the insulating layer, a state in which the constituent material of the second insulating portion 181B is present between the penetration hole formed in advance and the cathode penetration hole 162 is obtained. Thereafter, the inner wall surface of the cathode penetration hole 162 is metallized with a low-resistance metal such as copper, gold, or silver, and thus the cathode through-hole conductor 112B is formed. In a case of forming the cathode through-hole conductor 112B, for example, the inner wall surface of the cathode penetration hole 162 is metallized by an electroless copper plating treatment, an electrolytic copper plating treatment, or the like, and thus the processing is facilitated. In addition, a method of forming the cathode through-hole conductor 112B may be a method of filling the cathode penetration hole 162 with a metal, a composite material of a metal and a resin, or the like, in addition to a method of metallizing the inner wall surface of the cathode penetration hole 162.

Examples of a constituent material of the cathode connection terminal layer 113B include a low-resistance metal such as silver, gold, or copper. In this case, the cathode connection terminal layer 113B is formed, for example, by performing a plating treatment on the surface of the cathode through-hole conductor 112B.

In order to improve the adhesion between the cathode connection terminal layer 113B and the other member, here, in order to improve the adhesion between the cathode connection terminal layer 113B and the cathode through-hole conductor 112B, a mixed material of a resin and at least one conductive filler selected from the group consisting of a silver filler, a copper filler, a nickel filler, and a carbon filler may be used as a constituent material of the cathode connection terminal layer 113B.

Examples of the constituent material of the via conductor 182 include the same constituent material as the constituent material of the cathode connection terminal layer 113B.

The via conductor 182 is formed, for example, by performing a plating treatment on an inner wall surface with respect to a penetration hole provided to penetrate the insulating portion 181 in the thickness direction T or performing a heat treatment after filling the penetration hole with a conductive paste.

As illustrated in FIGS. 7 and 8, it is preferable that the module 110 further includes a second resin filling portion 171B in which the cathode penetration hole 162 is filled with a resin material. In the examples illustrated in FIGS. 7 and 8, the second resin filling portion 171B is provided in a space surrounded by the cathode through-hole conductor 112B on the inner wall surface of the cathode penetration hole 162. In a case where the second resin filling portion 171B is provided to eliminate the space in the cathode penetration hole 162, the occurrence of delamination of the cathode through-hole conductor 112B is suppressed.

It is preferable that the coefficient of thermal expansion of the second resin filling portion 171B is greater than the coefficient of thermal expansion of the cathode through-hole conductor 112B. More specifically, it is preferable that the coefficient of thermal expansion of the resin material with which the cathode penetration hole 162 is filled is greater than the coefficient of thermal expansion of the constituent material (for example, copper) of the cathode through-hole conductor 112B. In this case, in a case where the second resin filling portion 171B, more specifically, the resin material filled in the cathode penetration hole 162 expands in the high temperature environment, the cathode through-hole conductor 112B is pressed against the inner wall surface of the cathode penetration hole 162 from the inner side portion toward the outer side portion of the cathode penetration hole 162, and thus the occurrence of delamination of the cathode through-hole conductor 112B is sufficiently suppressed.

The coefficient of thermal expansion of the second resin filling portion 171B may be the same as the coefficient of thermal expansion of the cathode through-hole conductor 112B or may be less than the coefficient of thermal expansion of the cathode through-hole conductor 112B. More specifically, the coefficient of thermal expansion of the resin material with which the cathode penetration hole 162 is filled may be the same as the coefficient of thermal expansion of the constituent material of the cathode through-hole conductor 112B or may be less than the coefficient of thermal expansion of the constituent material of the cathode through-hole conductor 112B.

The module 110 does not need to have the second resin filling portion 171B. In this case, it is preferable that the cathode through-hole conductor 112B is provided not only on the inner wall surface of the cathode penetration hole 162 but also on the entire or a portion of the inside of the cathode penetration hole 162.

As illustrated in FIG. 7, it is preferable that the module 110 further includes a second insulating layer 180B in which the porous layer 154 is filled with an insulating material. In this case, the insulation between the anode plate 151 and the cathode layer 156 is secured, and thus the short circuit therebetween is prevented.

As illustrated in FIG. 7, it is preferable that the second insulating layer 180B is provided not only inside the porous layer 154 but also on the surface of the capacitor array 111, more specifically, on the surface of the dielectric layer in which the cathode layer 156 is not present on the surface of the capacitor portion 150. In this case, the insulation between the anode plate 151 and the cathode layer 156 is sufficiently secured, and thus the short circuit therebetween is sufficiently prevented.

As illustrated in FIGS. 7 and 8, it is preferable that the second insulating layer 180B is provided around the cathode through-hole conductor 112B. In this case, the insulation between the anode plate 151 and the cathode layer 156 is sufficiently secured, and thus the short circuit therebetween is sufficiently prevented. Further, since the second insulating layer 180B functions as a barrier layer with respect to the anode plate 151, more specifically, as a barrier layer with respect to the core portion 152 and the porous layer 154, the dissolution of the end surface of the anode plate 151 that occurs during the chemical liquid treatment for forming the cathode connection terminal layer 113B and the like is suppressed, and thus the infiltration of chemical liquid into the capacitor portion 150 is suppressed. Therefore, the reliability of the capacitor portion 150 is likely to be improved, and as a result, the reliability of the module 110 is likely to be improved.

From the viewpoint of enhancing the above-described effect, as illustrated in FIG. 7, it is preferable that the dimension of the second insulating layer 180B is greater than the dimension of the porous layer 154 in the thickness direction T.

Examples of a constituent material of the second insulating layer 180B include a resin material such as epoxy, phenol, or polyimide, and a mixed material of the resin material such as epoxy, phenol, or polyimide and an inorganic filler such as silica or alumina.

In a case where the module 110 has the first insulating portion 181A and the second insulating portion 181B, as illustrated in FIG. 7, it is preferable that the second insulating portion 181B extends between the anode plate 151 and the cathode through-hole conductor 112B. In the example illustrated in FIG. 7, the second insulating portion 181B is in contact with both the anode plate 151 and the cathode through-hole conductor 112B. Since the second insulating portion 181B extends between the anode plate 151 and the cathode through-hole conductor 112B, the insulation between the anode plate 151 and the cathode through-hole conductor 112B and the insulation between the anode plate 151 and the cathode layer 156 are secured, and thus the short circuit therebetween is prevented.

In a case where the second insulating portion 181B extends between the anode plate 151 and the cathode through-hole conductor 112B, as illustrated in FIG. 7, it is preferable that the core portion 152 and the porous layer 154 are exposed on the end surface of the anode plate 151 which is in contact with the second insulating portion 181B. In this case, in a case where the contact area between the second insulating portion 181B and the porous layer 154 is increased, the adhesion between the second insulating portion 181B and the porous layer 154 is improved, and thus a problem such as peeling between the second insulating portion 181B and the porous layer 154 is less likely to occur.

In a case where the core portion 152 and the porous layer 154 are exposed on the end surface of the anode plate 151 which is in contact with the second insulating portion 181B, as illustrated in FIGS. 7 and 8, it is preferable that the second insulating layer 180B that spreads inside the porous layer 154 by the insulating material entering the voids of the porous layer 154 is provided around the cathode through-hole conductor 112B. In this case, the insulation between the anode plate 151 and the cathode through-hole conductor 112B and the insulation between the anode plate 151 and the cathode layer 156 is sufficiently secured, and the short circuit therebetween is sufficiently prevented.

In a case where the core portion 152 and the porous layer 154 are exposed on the end surface of the anode plate 151 which is in contact with the second insulating portion 181B, it is preferable that the constituent material of the second insulating portion 181B enters the voids of the porous layer 154. In this case, the mechanical strength of the porous layer 154 is improved, and the occurrence of delamination due to the voids of the porous layer 154 is suppressed.

It is preferable that the coefficient of thermal expansion of the second insulating portion 181B is greater than the coefficient of thermal expansion of the cathode through-hole conductor 112B. More specifically, it is preferable that the coefficient of thermal expansion of the constituent material of the second insulating portion 181B is greater than the coefficient of thermal expansion of the constituent material (for example, copper) of the cathode through-hole conductor 112B. In this case, in a case where the second insulating portion 181B, more specifically, the constituent material of the second insulating portion 181B expands in the high temperature environment, the porous layer 154 and the cathode through-hole conductor 112B are pressed, and thus the occurrence of delamination is sufficiently suppressed.

The coefficient of thermal expansion of the second insulating portion 181B may be the same as the coefficient of thermal expansion of the cathode through-hole conductor 112B, or may be less than the coefficient of thermal expansion of the cathode through-hole conductor 112B. More specifically, the coefficient of thermal expansion of the constituent material of the second insulating portion 181B may be the same as the coefficient of thermal expansion of the constituent material of the cathode through-hole conductor 112B, or may be less than the coefficient of thermal expansion of the constituent material of the cathode through-hole conductor 112B.

In the module 10A illustrated in FIG. 2, the first through-hole conductor 12a includes, for example, at least one of the anode through-hole conductor 112A illustrated in FIGS. 5 and 6 and the cathode through-hole conductor 112B illustrated in FIGS. 7 and 8. For example, in the module 10A, in the first through-hole conductor 12a, the first through-hole conductor 12aa may be one of the anode through-hole conductor 112A and the cathode through-hole conductor 112B, and the first through-hole conductor 12ab may be the other of the anode through-hole conductor 112A and the cathode through-hole conductor 112B.

In a case where the module 10A includes a through-hole conductor that is electrically connected to the capacitor portion C1 or the capacitor portion C2 forming the first capacitor array 11a, the module 10A may further include a through-hole conductor that is not electrically connected to the capacitor portion C1 and the capacitor portion C2.

Examples of the through-hole conductor that is not electrically connected to the capacitor portion include a through-hole conductor for an I/O line. An insulating material is filled between the through-hole conductor for an I/O line and the penetration hole that is provided with the through-hole conductor and penetrating the capacitor portion in the thickness direction.

In a case where, for example, the module 10A includes a through-hole conductor for an I/O line is included as the through-hole conductor that is not electrically connected to the capacitor portion C1 and the capacitor portion C2, the design degree of freedom of the semiconductor composite apparatus 1A is improved, and the size of the semiconductor composite apparatus 1A can be reduced.

In the module 10A illustrated in FIG. 2, the first connection terminal layer 13a includes, for example, at least one of the anode connection terminal layer 113A illustrated in FIGS. 5 and 6 and the cathode connection terminal layer 113B illustrated in FIGS. 7 and 8. For example, in the module 10A, in the first connection terminal layer 13a, the first connection terminal layer 13aa may be one of the anode connection terminal layer 113A and the cathode connection terminal layer 113B, and the first connection terminal layer 13ab may be the other of the anode connection terminal layer 113A and the cathode connection terminal layer 113B.

In the module 10A illustrated in FIG. 2, the second through-hole conductor 12b includes, for example, at least one of the anode through-hole conductor 112A illustrated in FIGS. 5 and 6 and the cathode through-hole conductor 112B illustrated in FIGS. 7 and 8. For example, in the module 10A, in the second through-hole conductors 12b, the second through-hole conductor 12ba may be one of the anode through-hole conductor 112A and the cathode through-hole conductor 112B, and the second through-hole conductor 12bb may be the other of the anode through-hole conductor 112A and the cathode through-hole conductor 112B.

In a case where the module 10A includes a through-hole conductor that is electrically connected to the capacitor portion C3 or the capacitor portion C4 forming the second capacitor array 11b, the module 10A may further include a through-hole conductor that is not electrically connected to the capacitor portion C3 and the capacitor portion C4.

In a case where, for example, the module 10A includes a through-hole conductor for I/O line as the through-hole conductor that is not electrically connected to the capacitor portion C3 and the capacitor portion C4, the design degree of freedom of the semiconductor composite apparatus 1A is improved and the size of the semiconductor composite apparatus 1A can be reduced.

In the module 10A illustrated in FIG. 2, the second connection terminal layer 13b includes, for example, at least one of the anode connection terminal layer 113A illustrated in FIGS. 5 and 6 and the cathode connection terminal layer 113B illustrated in FIGS. 7 and 8. For example, in the module 10A, in the second connection terminal layer 13b, the second connection terminal layer 13ba may be one of the anode connection terminal layer 113A and the cathode connection terminal layer 113B, and the second connection terminal layer 13bb may be the other of the anode connection terminal layer 113A and the cathode connection terminal layer 113B.

In a semiconductor composite apparatus according to aspects of the present disclosure, the wiring board may include a first wiring board and a second wiring board, the first capacitor array may be built in the first wiring board, and the second capacitor array may be built in the second wiring board. The semiconductor composite apparatus according to such an aspect will be described as a semiconductor composite apparatus.

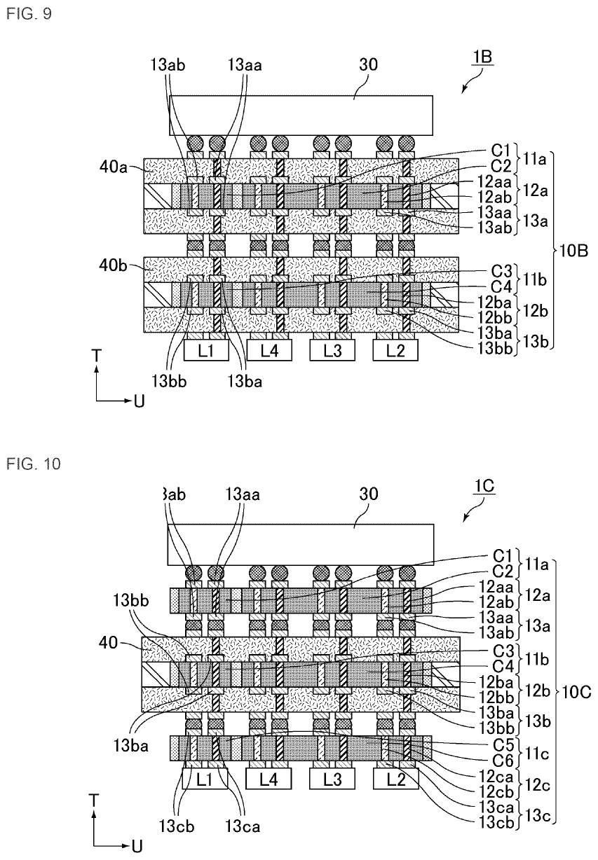

FIG. 9 is a schematic cross-sectional view illustrating an example of the semiconductor composite apparatus according to aspects of the present disclosure.

In a semiconductor composite apparatus 1B illustrated in FIG. 9, the module 10B has the first capacitor array 11a, the second capacitor array 11b, the first through-hole conductor 12a, the second through-hole conductor 12b, the first connection terminal layer 13a, and the second connection terminal layer 13b, as the same as in the module 10A illustrated in FIG. 2.

In the semiconductor composite apparatus 1B, the first capacitor array 11a is built in a first wiring board 40a, and the second capacitor array 11b is built in the second wiring board 40b.

In addition, the first through-hole conductor 12a and the first connection terminal layer 13a, which correspond to the first capacitor array 11a, are built in the first wiring board 40a, and the second through-hole conductor 12b and the second connection terminal layer 13b, which correspond to the second capacitor array 11b, are built in the second wiring board 40b.

In a semiconductor composite apparatus according to aspects of the present disclosure, the capacitor array may further include a third capacitor array, the first capacitor array may be provided on one mounting surface of the wiring board, the second capacitor array may be built in the wiring board, and the third capacitor array may be provided on the other mounting surface of the wiring board. The semiconductor composite apparatus according to such an aspect will be described as a semiconductor composite apparatus according to aspects of the present disclosure.

FIG. 10 is a schematic cross-sectional view illustrating an example of the semiconductor composite apparatus according to aspects of the present disclosure.

In a semiconductor composite apparatus 1C illustrated in FIG. 10, a module 10C includes a first capacitor array 11a, a second capacitor array 11b, a third capacitor array 11c, a first through-hole conductor 12a, a second through-hole conductor 12b, a third through-hole conductor 12c, a first connection terminal layer 13a, a second connection terminal layer 13b, and a third connection terminal layer 13c.

The third capacitor array 11c includes a plurality of capacitor portions disposed in a plane. In the example illustrated in FIG. 10, the third capacitor array 11c includes two capacitor portions disposed in a plane, more specifically, a capacitor portion C5 and a capacitor portion C6.

When viewed from a thickness direction T, the areas of the capacitor portion C5 and the capacitor portion C6 may be the same as each other or different from each other.

The third capacitor array 11c may include three or more capacitor portions disposed in a plane.

The third through-hole conductor 12c is provided to penetrate the capacitor portion C5 or the capacitor portion C6 in the thickness direction T of the third capacitor array 11c. In the example illustrated in FIG. 10, the third through-hole conductor 12c includes a third through-hole conductor 12ca and a third through-hole conductor 12cb. The third through-hole conductor 12ca and the third through-hole conductor 12cb are provided to penetrate the capacitor portion C5 in the thickness direction T, and are provided to penetrate the capacitor portion C6 in the thickness direction T.

The third through-hole conductor 12c is used for electrical connection between the capacitor portion C5 and at least one of the voltage regulator 20 (see FIG. 4) and the load 30. In the example illustrated in FIG. 10, the third through-hole conductor 12ca and the third through-hole conductor 12cb, which are included in the third through-hole conductor 12c corresponding to the capacitor portion C5, are used for electrical connection between the capacitor portion C5 and the bolt voltage regulator 20, respectively.

The third through-hole conductor 12c is used for electrical connection between the capacitor portion C6 and at least one of the bolt voltage regulator 20 (see FIG. 4) and the load 30. In the example illustrated in FIG. 10, the third through-hole conductor 12ca and the third through-hole conductor 12cb, which are included in the third through-hole conductor 12c corresponding to the capacitor portion C6, are used for electrical connection between the capacitor portion C6 and the voltage regulator 20, respectively.

The third through-hole conductor 12c includes, for example, at least one of the anode through-hole conductor 112A illustrated in FIGS. 5 and 6 and the cathode through-hole conductor 112B illustrated in FIGS. 7 and 8. For example, in the third through-hole conductor 12c, the third through-hole conductor 12ca may be one of the anode through-hole conductor 112A and the cathode through-hole conductor 112B, and the third through-hole conductor 12cb may be the other of the anode through-hole conductor 112A and the cathode through-hole conductor 112B.

In a case where the module 10C includes a through-hole conductor that is electrically connected to the capacitor portion C5 or the capacitor portion C6 forming the third capacitor array 11c, the module 10C may further include a through-hole conductor that is not electrically connected to the capacitor portion C5 and the capacitor portion C6.

In a case where, for example, the module 10C includes a through-hole conductor for an I/O line as the through-hole conductor that is not electrically connected to the capacitor portion C5 and the capacitor portion C6, the design freedom of the semiconductor composite apparatus 1C is improved, and the size of the semiconductor composite apparatus 1C can be reduced.

The third connection terminal layer 13c is electrically connected to the third through-hole conductor 12c. In the example illustrated in FIG. 10, the third connection terminal layer 13c includes a third connection terminal layer 13ca and a third connection terminal layer 13cb. The third connection terminal layer 13ca is provided on both ends of the third through-hole conductor 12ca and is connected to the third through-hole conductor 12ca. The third connection terminal layer 13cb is provided on both ends of the third through-hole conductor 12cb and is connected to the third through-hole conductor 12cb.

The third connection terminal layer 13c is used for electrical connection between the capacitor portion C5 and at least one of the voltage regulator 20 (refer to FIG. 4) and the load 30. In the example illustrated in FIG. 10, in the third connection terminal layer 13ca and the third connection terminal layer 13cb included in the third connection terminal layer 13c corresponding to the capacitor portion C5, the connection terminal layers (in FIG. 10, the third connection terminal layer 13ca and the third connection terminal layer 13cb on the lower side) present on the side of the voltage regulator 20 are used for the electrical connection between the capacitor portion C5 and the voltage regulator 20.

The third connection terminal layer 13c is used for electrical connection between the capacitor portion C6 and at least one of the voltage regulator 20 (see FIG. 4) and the load 30. In the example illustrated in FIG. 10, in the third connection terminal layer 13ca and the third connection terminal layer 13cb included in the third connection terminal layer 13c corresponding to the capacitor portion C6, the connection terminal layers (in FIG. 10, the third connection terminal layer 13ca and the third connection terminal layer 13cb on the lower side) present on the side of the voltage regulator 20 are used for the electrical connection between the capacitor portion C6 and the voltage regulator 20.

The third connection terminal layer 13c includes, for example, at least one of the anode connection terminal layer 113A illustrated in FIGS. 5 and 6 and the cathode connection terminal layer 113B illustrated in FIGS. 7 and 8. For example, in the third connection terminal layer 13c, the third connection terminal layer 13ca may be one of the anode connection terminal layer 113A and the cathode connection terminal layer 113B, and the third connection terminal layer 13cb may be the other of the anode connection terminal layer 113A and the cathode connection terminal layer 113B.

In the module 10C, when viewed from the mounting surface of the first connection terminal layer 13a or the third connection terminal layer 13c, it is preferable that at least a part of the first through-hole conductor 12aa, at least a part of the first connection terminal layer 13aa, at least a part of the second through-hole conductor 12ba, at least a part of the second connection terminal layer 13ba, at least a part of the third through-hole conductor 12ca, and at least a part of the third connection terminal layer 13ca overlap each other. Alternatively, in the module 10C, when viewed from the mounting surface of the first connection terminal layer 13a or the third connection terminal layer 13c, it is preferable that the first through-hole conductor 12aa, the first connection terminal layer 13aa, the second through-hole conductor 12ba, the second connection terminal layer 13ba, the third through-hole conductor 12ca, and the third connection terminal layer 13ca are positioned on the same straight line along the thickness direction T.

In the module 10C, when viewed from the mounting surface of the first connection terminal layer 13a or the third connection terminal layer 13c, it is preferable that at least a part of the first through-hole conductor 12ab, at least a part of the first connection terminal layer 13ab, at least a part of the second through-hole conductor 12bb, at least a part of the second connection terminal layer 13bb, at least a part of the third through-hole conductor 12cb, and at least a part of the third connection terminal layer 13cb overlap each other. Alternatively, in the module 10C, when viewed from the mounting surface of the first connection terminal layer 13a or the third connection terminal layer 13c, it is preferable that the first through-hole conductor 12ab, the first connection terminal layer 13ab, the second through-hole conductor 12bb, the second connection terminal layer 13bb, the third through-hole conductor 12cb, and the third connection terminal layer 13cb are positioned on the same straight line along the thickness direction T.

In the module according to aspects of the present disclosure, the capacitor array may further include a third capacitor array, and, when viewed from the mounting surface of the connection terminal layer, it is preferable that at least a part of the first capacitor array, at least a part of the second capacitor array, and at least a part of the third capacitor array overlap each other.

In the module 10C, when viewed from the mounting surface of the first connection terminal layer 13a or the third connection terminal layer 13c, it is preferable that at least a part of the first capacitor array 11a, at least a part of the second capacitor array 11b, and at least a part of the third capacitor array 11c overlap each other. More specifically, in the module 10C, when viewed from the mounting surface of the first connection terminal layer 13a or the third connection terminal layer 13c, it is preferable that at least a part of the capacitor portions (in the example illustrated in FIG. 10, the capacitor portion C1 and the capacitor portion C2) forming the first capacitor array 11a, at least a part of the capacitor portions (in the example illustrated in FIG. 10, the capacitor portion C3 and the capacitor portion C4) forming the second capacitor array 11b, and at least a part of the capacitor portions (in the example illustrated in FIG. 10, the capacitor portion C5 and the capacitor portion C6) forming the third capacitor array 11c overlap each other.

In the module 10C, when viewed from the mounting surface of the first connection terminal layer 13a or the third connection terminal layer 13c, it is particularly preferable that the entire or a portion of the first capacitor array 11a, the entire or a portion of the second capacitor array 11b, and the entire or a portion of the third capacitor array 11c overlap each other.

In the module 10C, when viewed from the mounting surface of the first connection terminal layer 13a or the third connection terminal layer 13c, at least a part of the first capacitor array 11a, at least a part of the second capacitor array 11b, and at least a part of the third capacitor array 11c overlap each other, and thus the first capacitor array 11a, the second capacitor array 11b, and the third capacitor array 11c are not disposed on the same plane that spreads in the surface direction U. Therefore, a wiring path between the first capacitor array 11a and the second capacitor array 11b and a wiring path between the second capacitor array 11b and the third capacitor array 11c are likely to be shortened, and, as a result, the loss due to wiring can be reduced.

In the semiconductor composite apparatus according to aspects of the present disclosure, the capacitor array may further include a third capacitor array, the first capacitor array may be provided on one mounting surface of the wiring board, the second capacitor array may be built in the wiring board, and the third capacitor array may be provided on the other mounting surface of the wiring board.

In the example illustrated in FIG. 10, the first capacitor array 11a is provided on one mounting surface of the wiring board 40, the second capacitor array 11b is built in the wiring board 40, and the third capacitor array 11c is provided on the other mounting surface of the wiring board 40.

The first capacitor array 11a may be built in the wiring board 40 or may be built in a wiring board different from the wiring board 40. In addition, the second capacitor array 11b may be provided on one or the other mounting surface of the wiring board 40. In addition, the third capacitor array 11c may be built in the wiring board 40 or may be built in a wiring board different from the wiring board 40.

In the above disclosure, an example of an aspect in which the module according to aspects of the present disclosure includes two or three capacitor arrays has been described, but the module according to aspects of the present disclosure may include four or more capacitor arrays.

A circuit configuration of the semiconductor composite apparatus according to the present disclosure may be other than the circuit configuration illustrated in FIG. 1.

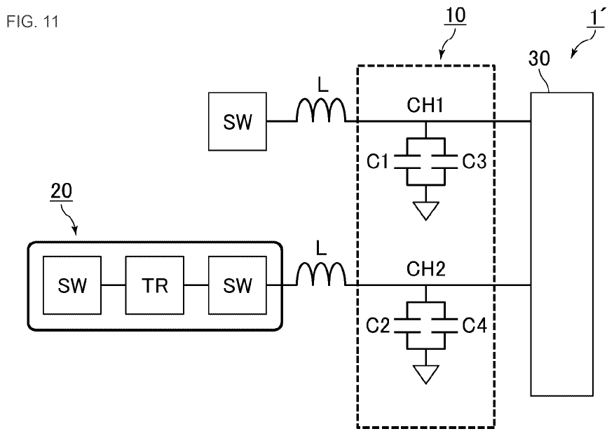

FIG. 11 is a circuit configuration diagram illustrating another example of a circuit configuration of the semiconductor composite apparatus according to the present disclosure.

As in a semiconductor composite apparatus 1′ illustrated in FIG. 11, a voltage regulator 20 may include a transformer TR in addition to a switching element SW.

In the semiconductor composite apparatus 1′, the voltage regulator 20 does not need to include the switching element SW of a front stage (left side in FIG. 11) of the transformer TR. In addition, in the semiconductor composite apparatus 1′, the voltage regulator 20 may include the switching element SW or the inductor L provided in the first channel CH1.

In general, the description of the aspects disclosed should be considered as being illustrative in all respects and not being restrictive. The scope of the present invention is shown by the claims rather than by the above description, and is intended to include meanings equivalent to the claims and all changes in the scope. While preferred aspects of the invention have been described above, it is to be understood that variations and modifications will be apparent to those skilled in the art without departing from the scope and spirit of the invention.

### REFERENCE SIGNS LIST

1, 1′, 1A, 1B, 1C: SEMICONDUCTOR COMPOSITE APPARATUS
10, 10A, 10B, 10C, 110: MODULE
11a: FIRST CAPACITOR ARRAY
11b: SECOND CAPACITOR ARRAY
11c: THIRD CAPACITOR ARRAY
12a, 12aa, 12ab: FIRST THROUGH-HOLE CONDUCTOR
12b, 12ba, 12bb: SECOND THROUGH-HOLE CONDUCTOR
12c, 12ca, 12cb: THIRD THROUGH-HOLE CONDUCTOR
13a, 13aa, 13ab: FIRST CONNECTION TERMINAL LAYER
13b, 13ba, 13bb: SECOND CONNECTION TERMINAL LAYER
13c, 13ca, 13cb: THIRD CONNECTION TERMINAL LAYER
20: VOLTAGE REGULATOR
30: LOAD
40: WIRING BOARD
40a: FIRST WIRING BOARD
40b: SECOND WIRING BOARD
45: CIRCUIT LAYER
111: CAPACITOR ARRAY
112A: ANODE THROUGH-HOLE CONDUCTOR
112B: CATHODE THROUGH-HOLE CONDUCTOR
113A: ANODE CONNECTION TERMINAL LAYER
113B: CATHODE CONNECTION TERMINAL LAYER
150: CAPACITOR PORTION
151: ANODE PLATE
152: CORE PORTION
154: POROUS LAYER
156: CATHODE LAYER
156A: SOLID ELECTROLYTE LAYER
156B: CONDUCTOR LAYER
161: ANODE PENETRATION HOLE
162: CATHODE PENETRATION HOLE
170: ANODE CONNECTION LAYER
170A: FIRST ANODE CONNECTION LAYER
170B: SECOND ANODE CONNECTION LAYER
171A: FIRST RESIN FILLING PORTION
171B: SECOND RESIN FILLING PORTION
180A: FIRST INSULATING LAYER
180B: SECOND INSULATING LAYER
181: INSULATING PORTION
181A: FIRST INSULATING PORTION
181B: SECOND INSULATING PORTION
182: VIA CONDUCTOR
C1, C2, C3, C4, C5, C6: CAPACITOR PORTION
CH1: FIRST CHANNEL
CH2: SECOND CHANNEL
L, L1, L2, L3, L4: INDUCTOR
SW, SW1, SW2, SW3, SW4: SWITCHING ELEMENT
T: THICKNESS DIRECTION
TR: TRANSFORMER
U: SURFACE DIRECTION

What is claimed:

1. A module configured for a semiconductor composite apparatus in which a direct current voltage adjusted by a voltage regulator including a semiconductor active element is supplied to a load, the module comprising:
a capacitor array that is configured with a plurality of capacitor portions disposed in a plane;
a through-hole conductor that penetrates the plurality of capacitor portions in a thickness direction of the capacitor array and provides an electrical connection between the plurality of capacitor portions and at least one of the voltage regulator and the load; and
a connection terminal layer electrically connected to the through-hole conductor and is used for electrical connection between the plurality of capacitor portions and at least one of the voltage regulator and the load,
wherein the capacitor array includes at least a first capacitor array and a second capacitor array, and, when viewed from a mounting surface of the connection terminal layer, at least a part of the first capacitor array overlaps at least a part of the second capacitor array.

2. The module according to claim 1, wherein a difference between a withstanding voltage of the first capacitor array and a withstanding voltage of the second capacitor array is 1 V or greater.

3. The module according to claim 1, wherein:
the capacitor array further includes a third capacitor array, and
when viewed from the mounting surface of the connection terminal layer, at least a part of the first capacitor array, at least a part of the second capacitor array, and at least a part of the third capacitor array overlap each other.

4. A semiconductor composite apparatus comprising:
the module according to claim 1;
the voltage regulator; and
the load.

5. The semiconductor composite apparatus according to claim 4, wherein, when viewed from the mounting surface of the connection terminal layer, at least a part of the semiconductor active element included in the voltage regulator overlaps the first capacitor array and the second capacitor array.

6. The semiconductor composite apparatus according to claim 4, wherein, when viewed from the mounting surface of the connection terminal layer, at least a part of the first capacitor array and at least a part of the second capacitor array overlap the load.

7. The semiconductor composite apparatus according to claim 4, further comprising a wiring board that is electrically connected to the voltage regulator and the load.

8. The semiconductor composite apparatus according to claim 7, wherein one of the first capacitor array and the second capacitor array is on a mounting surface of the wiring board, and another of the first capacitor array and the second capacitor array is in the wiring board.

9. The semiconductor composite apparatus according to claim 7, wherein:
the wiring board includes a first wiring board and a second wiring board,
the first capacitor array is in the first wiring board, and
the second capacitor array is in the second wiring board.

10. The semiconductor composite apparatus according to claim 7, wherein:
the capacitor array further includes a third capacitor array,
the first capacitor array is on one mounting surface of the wiring board,
the second capacitor array is in the wiring board, and
the third capacitor array is on another mounting surface of the wiring board.

11. A module configured for a semiconductor composite apparatus, the module comprising:
a capacitor array including a first array and a second array including a plurality of capacitor portions disposed in a plane;
a through-hole conductor that penetrates the plurality of capacitor portions in a thickness direction of the capacitor array and provides an electrical connection between the plurality of capacitor portions and a voltage regulator or a load;
a connection terminal layer that is electrically connected to the through-hole conductor and that provides an electrical connection between the plurality of capacitor portions and the voltage regulator or the load; and
a wiring board configured to be connected to the voltage regulator and the load;
wherein, when the capacitor array is viewed from a mounting surface of the connection terminal layer, at least a portion of the first array overlaps at least a portion of the second array, and
wherein the first array or the second array are disposed on a mounting surface of the wiring board.

12. The module according to claim 11, wherein the first array or the second array are disposed in the wiring board.

13. The module according to claim 11, wherein a difference between a withstanding voltage of the first array and a withstanding voltage of the second array is 1V or greater.

14. The module according to claim 11, wherein:
the capacitor array further includes a third array, and
when viewed from the mounting surface of the connection terminal layer, a portion of the first array, a portion of the second array, and a portion of the third array overlap each other.

15. A semiconductor composite apparatus comprising:
a voltage regulator;
a load;
a capacitor array including a first array and a second array including a plurality of capacitor portions disposed in a plane;
a through-hole conductor that penetrates the plurality of capacitor portions in a thickness direction of the capacitor array and that provides an electrical connection between the plurality of capacitor portions and the voltage regulator or the load;
a connection terminal layer electrically connected to the through-hole conductor and that provides an electrical connection between the plurality of capacitor portions and the voltage regulator or the load; and
a wiring board configured to be connected to the voltage regulator and the load;
wherein, when the capacitor array is viewed from a mounting surface of the connection terminal layer, at least a portion of the first array overlaps at least a portion of the second array, and
wherein the first array or the second array are disposed on a mounting surface of the wiring board.

16. The semiconductor composite apparatus according to claim 15, wherein the first array or the second array are disposed in the wiring board.

17. The semiconductor composite apparatus according to claim 15, wherein, when viewed from the mounting surface of the connection terminal layer, a part of a semiconductor active element included in the voltage regulator overlaps the first array or the second array.

18. The semiconductor composite apparatus according to claim 15, wherein, when viewed from the mounting surface of the connection terminal layer, a part of the first array or a part of the second array overlap the load.

19. The semiconductor composite apparatus according to claim 15, wherein a difference between a withstanding voltage of the first array and a withstanding voltage of the second array is 1 V or greater.

20. The semiconductor composite apparatus according to claim 15, wherein:
the capacitor array further includes a third array, and
when viewed from the mounting surface of the connection terminal layer, a portion of the first array, a portion of the second array, and a portion of the third array overlap each other.
